(19) United States
(12) Patent Application Publication
(10) Pub. No.: US 2012/0107486 A1
(43) Pub. Date: May 3, 2012

(54) SEALANT COATING DEVICE AND DISPENSING METHOD THEREOF

(75) Inventors: Chengming He, Quangdong (CN); Chien-Pang Lee, Quangdong (CN); Yu-wu Huang, Quangdong (CN)

(73) Assignee: SHENZHEN CHINA STAR OPTOELECTRONICS TECHNOLOGY CO., LTD., Shenzhen (CN)

(21) Appl. No.: 12/997,501

(22) PCT Filed: Nov. 5, 2010
(86) PCT No.: PCT/CN10/78471

§ 371 Date: Dec. 10, 2010

(30) Foreign Application Priority Data
Nov. 1, 2010 (CN) 201010527429.8

(51) Int. Cl. C23C 16/52; B67D 7/80; H05B 1/02; B05C 11/00

(52) U.S. Cl. 427/8; 118/699; 222/146.5; 219/494

(57) ABSTRACT

The present invention provides a sealant coating device having a sealant receiving chamber and a nozzle formed on a lower portion of the sealant receiving chamber. The sealant coating device further has a heating device, and the heating device is installed around the sealant receiving chamber for heating a sealant material filled in the sealant receiving chamber. The present invention further provides a dispensing method of the sealant coating device, which has the following steps of: obtaining time during the sealant material stays in the sealant receiving chamber; calculating a target temperature of the sealant material according to the obtained time and a desired sealant viscosity value; heating the sealant material to the target temperature. The advantages of the present invention are to use the heating device to lower the sealant viscosity based on the characteristic of the sealant viscosity varied with the temperature. In a case that the sealant material stays in the sealant receiving chamber a period of time to cause the raise of the sealant viscosity, the heating device can be automatically started to lower the actual sealant viscosity to constantly keep in the desired sealant viscosity.

### FIELD OF THE INVENTION

The present invention relates to a manufacture field of liquid crystal displays, and more particularly to a sealant coating device and a dispensing method thereof.

### BACKGROUND OF THE INVENTION

In a traditional technology, large-size LCD (liquid crystal display) panels generally use an ODF (one drop filling) process to fill liquid crystal into the panels. The process firstly drops liquid crystal material evenly on a surface of a TFT (thin film transistor) substrate, and then uses a sealant coating machine to dispense an UV curving sealant material, followed by curing to solidify and form a ring-like sealant member. Then, the TFT glass substrate is disposed in a vacuum environment, and thus the TFT substrate and a color filter (CF) can be processed by a vacuum alignment operation, an attachment operation and then a curing operation in a sealant curing oven. Thus, a cell packaging process of the LCD panels can be finished to form a liquid crystal cell, so that a semi-product of the LCD panels is fabricated.

Referring now to FIG. 1, FIG. 1 is a curve diagram of a traditional sealant viscosity varied with time in a traditional technology. In the foregoing traditional technology, the process to form the sealant member is to stir a sealant material and then fill it into a sealant dispenser which is mounted on the sealant coating machine to coat the sealant material onto a margin of a TFT, CF or dummy substrate. The sealant material is dispensed by pressurizing the sealant dispenser, while the dispensing amount of the sealant material can be controlled by controlling the pressure. However, the sealant viscosity is gradually raised with the increase of the operation time. In addition, in the foregoing traditional technology, the process to form the sealant member is to stir the sealant material and then fill it into the sealant dispenser which is mounted on the sealant coating machine to form a sticky ring-like sealant member. However, the common problem is that the sealant viscosity is gradually raised with the increase of the operation time. FIG. 1 shows a curve diagram of a traditional sealant viscosity varied with time under the room temperature of 23° C. In this case, the solution of the traditional technology is to increase the pressure of dispensing the sealant material, in order to control the dispensing amount of the sealant material.

However, when the sealant viscosity of the sealant member is too high, it is very difficult to control the dispensing amount of the sealant material by simply using the pressure, wherein the dispensing pressure can not stably control the total amount of the dispensed sealant material. Thus, it may generally cause various problems including breakage, locally narrowing and abnormally coating of the sealant member formed by the sealant material.

### SUMMARY OF THE INVENTION

To solve the foregoing technological problems, the present invention is to provide a sealant coating device and a dispensing method thereof, which can suitably lower an actual sealant viscosity to constantly keep in a desired sealant viscosity value, so as to ensure a normal operation of forming sealant members.

To achieve the above object, the present invention provides a sealant coating device comprising a sealant receiving chamber and a nozzle formed on a lower portion of the sealant receiving chamber, characterized in that: the sealant coating device further comprises a heating device, and the heating device is used to obtain time during the sealant material stays in the sealant receiving chamber, to calculate a target temperature of the sealant material according to the obtained time and a desired sealant viscosity value, and to heat the sealant material to the target temperature, so as to lower an actual sealant viscosity to constantly keep in the desired sealant viscosity value.

As one possible technical solution, the heating device is a constant-temperature heating device which keeps the temperature of the sealant material in a predetermined temperature.

As one possible technical solution, a heating mode of the heating device is selected from one of resistance heating and microwave heating.

As one possible technical solution, the sealant material is selected from a UV curing sealant material.

As one possible technical solution, a detection mode of the sealant coating device for detecting the temperature of the sealant material is selected from one of infrared (IR) detection and thermocouple detection.

The present invention further provides a dispensing method of a sealant coating device comprising the following steps of: obtaining time during a sealant material stays in a sealant receiving chamber; calculating a target temperature of the sealant material according to the obtained time and a desired sealant viscosity value; and heating the sealant material to the target temperature, so as to lower an actual sealant viscosity to constantly keep in the desired sealant viscosity value.

As one possible technical solution, the steps of obtaining the time during the sealant material stays in the sealant receiving chamber comprises: periodically obtaining the time during the sealant material stays in the sealant receiving chamber.

As one possible technical solution, repeating to execute the foregoing step for each predetermined interval, in order to continuously adjust the target temperature of heating the sealant material for constantly keep the actual sealant viscosity.

As one possible technical solution, in the step of heating the sealant material, a heating mode is selected from one of resistance heating and microwave heating.

As one possible technical solution, the sealant material is selected from a UV curing sealant material.

As one possible technical solution, in the step of heating the sealant material to the target temperature, a detection mode of detecting the temperature of the sealant material is selected from one of infrared (IR) detection and thermocouple detection.

The present invention further provides a heating device comprising a first obtaining module obtaining time during a sealant material stays in a sealant receiving chamber; a second obtaining module calculating a target temperature of the sealant material according to the obtained time and a desired sealant viscosity value; and a heating module heating the sealant material to the target temperature, so as to lower an actual sealant viscosity to constantly keep in the desired sealant viscosity value.

As one possible technical solution, the first obtaining module periodically obtains the time during the sealant material stays in the sealant receiving chamber.

As one possible technical solution, the heating module uses one of resistance heating and microwave heating.

As one possible technical solution, the heating module has a temperature detection unit detecting the temperature of the sealant material, and the temperature detection unit uses one of infrared (IR) detection and thermocouple detection.

The advantages of the present invention are to use the heating device to lower the sealant viscosity based on the characteristic of the sealant viscosity varied with the temperature. In a case that the sealant material stays in the sealant receiving chamber a period of time to cause the raise of the sealant viscosity, the heating device can be started to lower the actual sealant viscosity to constantly keep in the desired sealant viscosity.

### DESCRIPTION OF THE DRAWINGS

FIG. 1 is a curve diagram of a traditional sealant viscosity varied with time in a traditional technology;

FIG. 2 is a schematic view of a structure of a sealant coating device according to a preferred embodiment of the present invention;

FIG. 3 is a curve diagram of a sealant viscosity varied with temperature; and

FIG. 4 is a flow chart of steps of a dispensing method according to the preferred embodiment of the present invention.

### DETAILED DESCRIPTION OF THE PREFERRED EMBODIMENTS

A sealant coating device and a dispensing method thereof according to a preferred embodiment of the present invention are described more detailed by referring to the following detailed description and the accompanying drawings.

The objects, features and advantages of the present invention can be best understood by referring to the following detailed description of the preferred embodiments and the accompanying drawings. The specification of the present invention provides different embodiments to describe technical features of different implementation solutions, wherein arrangement of various elements in the embodiments is used to clearly describe the content of the present invention, but the present invention is not limited thereto. Meanwhile, numerals of drawings are partially repeated between different embodiments for simplifying the description, but not for building the relationship between the different embodiments.

FIG. 2 is a schematic view of a structure of a sealant coating device according to a preferred embodiment of the present invention, wherein the sealant coating device comprises a sealant receiving chamber 11, and a nozzle 13 and a heating device 15. The sealant receiving chamber 11 is filled with a sealant material 110. The nozzle 13 is formed on a lower portion of the sealant receiving chamber 11, while an upper portion of the sealant receiving chamber 11 is provided with a pressurizing device (not-shown) which can increase the pressure in the sealant receiving chamber 11 to dispense the sealant material 110 from the nozzle 13 onto a margin of a TFT substrate, followed by processing the TFT substrate and a CF (color filter) substrate by a vacuum alignment operation, an attachment operation and then a curing operation in a sealant curing oven. Thus, a cell packaging process of LCD panels can be finished to form a liquid crystal cell. In addition, the heating device 15 is installed around the sealant receiving chamber 11 for heating the sealant material 110 filled in the sealant receiving chamber 11. The sealant material 110 is generally selected from UV curing sealant material.

The heating device 15 is used to obtain time during the sealant material 110 stays in the sealant receiving chamber 11, to calculate a target temperature of the sealant material 110 according to the obtained time and a desired sealant viscosity value of the sealant material 110, and to heat the sealant material 110 to the target temperature, so as to lower an actual sealant viscosity of the sealant material 110 to constantly keep in the desired sealant viscosity value.

The heating device 15 can be a constant-temperature heating device, wherein a heating mode thereof is selected from one of resistance heating and microwave heating. The so-called “resistance heating” means to wind resistance wires around the sealant receiving chamber 11, wherein a large current can pass through the resistance wires to generate heat energy to heat the sealant material 110 in the sealant receiving chamber 11. The so-called “microwave heating” means to install a microwave source around the sealant receiving chamber 11, wherein a electromagnetic coupling effect can be generated to heat the sealant material 110. In addition, the man skilled in the art also can select other heating means (such as high frequency heating) according to actual conditions.

The constant-temperature heating device has advantages of keeping the temperature of the sealant material in a predetermined temperature, wherein a temperature control mechanism thereof is to detect the temperature of to-be-heated substance (i.e. the sealant material in the embodiment) and then adjust the power of heating. Thus, the temperature of to-be-heated substance can be kept in the predetermined temperature. The method of detecting the temperature of the to-be-heated substance can be infrared (IR) detection, thermocouple detection or other detection method.

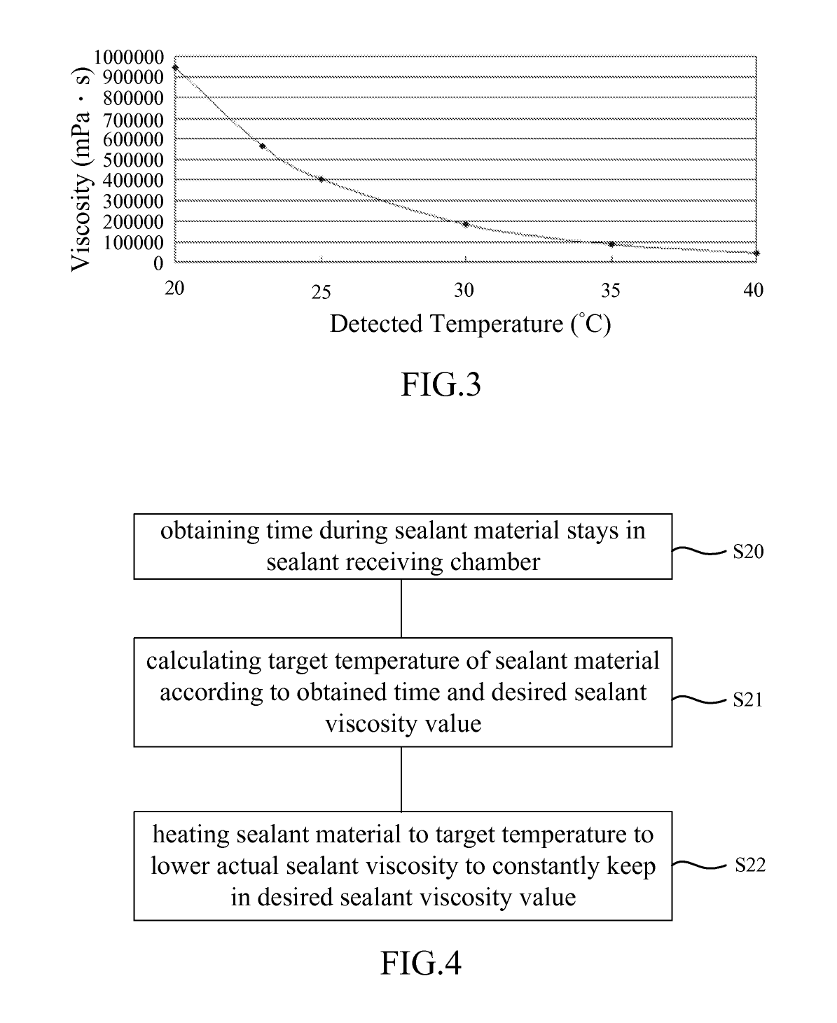

During executing the process, it can be found that the sealant viscosity of the sealant material 110 is related to the time during the sealant material 110 stays in the sealant receiving chamber 11, but also closely related to the temperature. The raise of the temperature is advantageous to lower the sealant viscosity of the sealant material 110. FIG. 3 is a curve diagram of a sealant viscosity varied with temperature, wherein the sealant viscosity of the sealant material 110 is gradually lowered when the temperature is raised from 20° C. to 40° C. Thus, in the embodiment, the heating device 15 can be used to lower the actual sealant viscosity of the sealant material 110. In a case that the sealant material 110 stays in the sealant receiving chamber 11 a period of time to cause the raise of the actual sealant viscosity, the heating device 15 can be started to lower the actual sealant viscosity to an initially desired sealant viscosity when the sealant material 110 is initially filled into the sealant receiving chamber 11, in order to constantly keep in the desired sealant viscosity.

FIG. 4 is a flow chart of steps of a dispensing method of the sealant coating device of FIG. 2, wherein the dispensing method comprises the following steps of:

In a step (S20), obtaining time during a sealant material stays in a sealant receiving chamber. In a case that it is surely necessary to compensate the sealant viscosity by heating, the time during the sealant material stays in the sealant receiving chamber can be easily recorded by recording the time of filling the sealant material. The step can periodically obtain the time during the sealant material stays in the sealant receiving chamber.

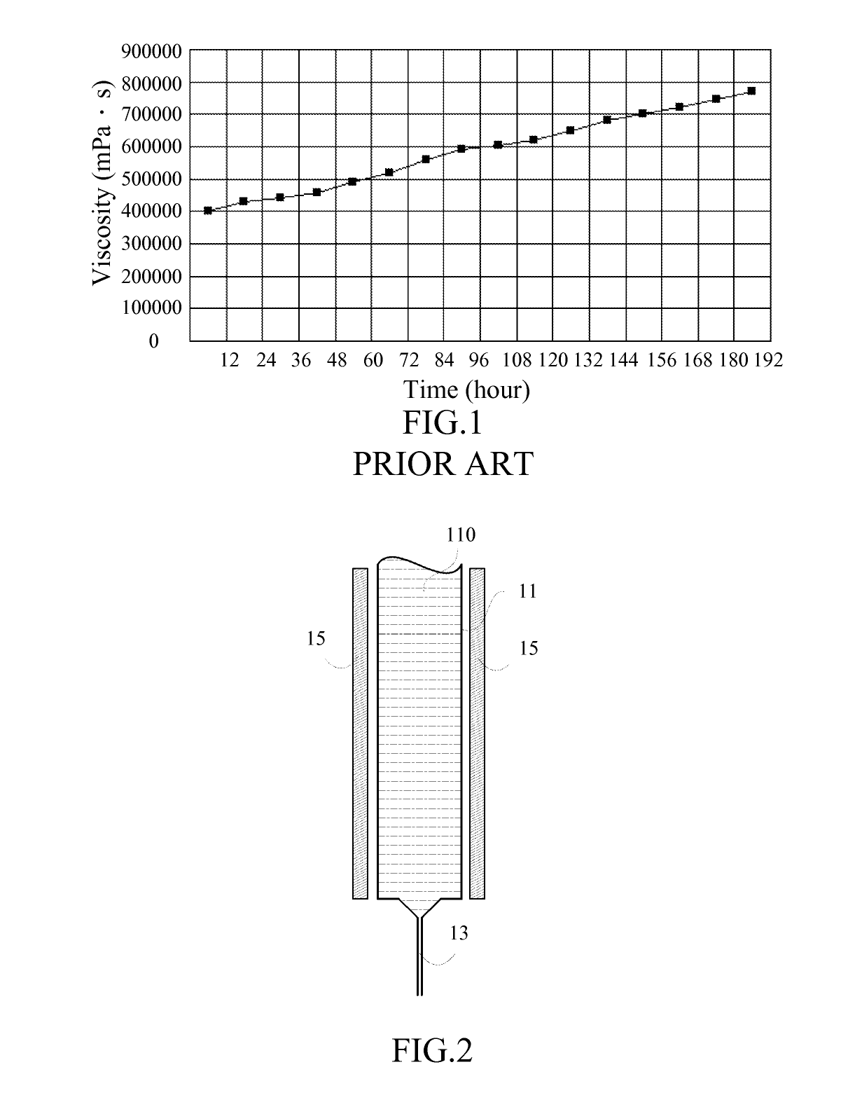

In a step (S21), calculating a target temperature of the sealant material according to the obtained time and a desired sealant viscosity value. The longer the sealant material stays in the sealant receiving chamber, the more apparently the sealant viscosity raises. Thus, it needs to consider the staying time to lower the sealant viscosity to the desired sealant viscosity value. Apparently, the longer the staying time is, the higher the target temperature of heating will be. In this case, the sealant viscosity will be lowered to a desired degree. A curve diagram of a sealant viscosity varied with time can be referring to FIG. 1, while a curve diagram of a sealant viscosity varied with temperature can be referring to FIG. 3.

In a step (S22), heating the sealant material to the target temperature, so as to lower an actual sealant viscosity to constantly keep in the desired sealant viscosity value. Heating to the target temperature means that the actual sealant viscosity has been lowered to the desired sealant viscosity value, and constantly kept in the desired sealant viscosity value. Thus, the following operations including dispensing and forming can be executed. The following steps are carried out according to conventional steps in the technological field of the present invention, and thus are omitted hereinafter.

In most cases, the dispensing process is continuously executed within a period of time, and thus a preferred method is to periodically repeat the foregoing steps (S20) to (S22), in order to continuously adjust the target temperature of heating the sealant material for constantly keeping the sealant viscosity without variation. The so-called “a period of time” can be one half hour, one hour, two hours and etc., wherein the man skilled in the art can flexibly adjust based on need of actual process precision. If the need of process precision is higher, the heating temperature can be adjusted with a shorter interval for stably controlling the sealant viscosity. On the other hand, if the need of process precision is not high, the interval can be suitably increased for enhancing the process efficiency.

Furthermore, a heating device according to a preferred embodiment of the present invention is disclosed hereinafter, wherein the device of the preferred embodiment comprises the following modules: a first obtaining module used for obtaining time during a sealant material stays in a sealant receiving chamber; a second obtaining module used for calculating a target temperature of the sealant material according to the time obtained by the first obtaining module and a desired sealant viscosity value; and a heating module used for heating the sealant material to the target temperature, so as to lower an actual sealant viscosity to constantly keep in the desired sealant viscosity value.

Preferably, the first obtaining module is used to periodically obtain the time during the sealant material stays in the sealant receiving chamber; the heating module can use one of resistance heating and microwave heating; the heating module has a temperature detection unit used for detecting the temperature of the sealant material; and the temperature detection unit uses one of infrared (IR) detection and thermocouple detection.

The operational principle of each of the modules can be referring to the content of the dispensing method of the sealant coating device according to the preferred embodiment of the present invention and FIG. 4, so that the detailed description thereof will be omitted herein.

The foregoing descriptions are only the preferred embodiment of the present invention, and it is understood that many changes and modifications to the described embodiment made by the man skilled in the art can be carried out without departing from the scope and the spirit of the invention that is intended to be limited only by the appended claims.

1. A sealant coating device, comprising a sealant receiving chamber and a nozzle formed on a lower portion of the sealant receiving chamber, characterized in that:
the sealant coating device further comprises a heating device, and the heating device obtains time during the sealant material stays in the sealant receiving chamber, calculates a target temperature of the sealant material according to the obtained time and a desired sealant viscosity value, and heats the sealant material to the target temperature, so as to lower an actual sealant viscosity to constantly keep in the desired sealant viscosity value.

2. The sealant coating device according to claim 1, characterized in that:
the heating device is a constant-temperature heating device which keeps the temperature of the sealant material in a predetermined temperature.

3. The sealant coating device according to claim 1, characterized in that:
a heating mode of the heating device is selected from one of resistance heating and microwave heating.

4. The sealant coating device according to claim 1, characterized in that:
the sealant material is selected from a UV curing sealant material.

5. The sealant coating device according to claim 1, characterized in that:
a detection mode of the sealant coating device to detect the temperature of the sealant material is selected from one of infrared detection and thermocouple detection.

6. A dispensing method of a sealant coating device according to claim 1, characterized in that: comprising the steps of:
obtaining time during a sealant material stays in a sealant receiving chamber;
calculating a target temperature of the sealant material according to the obtained time and a desired sealant viscosity value; and
heating the sealant material to the target temperature, so as to lower an actual sealant viscosity to constantly keep in the desired sealant viscosity value.

7. The dispensing method of the sealant coating device according to claim 6, characterized in that: the steps of obtaining the time during the sealant material stays in the sealant receiving chamber comprises: periodically obtaining the time during the sealant material stays in the sealant receiving chamber.

8. The dispensing method of the sealant coating device according to claim 6 or 7, characterized in that: in the step of heating the sealant material, a heating mode is selected from one of resistance heating and microwave heating.

9. The dispensing method of the sealant coating device according to claim 6 or 7, characterized in that: the sealant material is selected from a UV curing sealant material.

10. The dispensing method of the sealant coating device according to claim 6 or 7, characterized in that: in the step of heating the sealant material to the target temperature, a detection mode of detecting the temperature of the sealant material is selected from one of infrared detection and thermocouple detection.

11. A heating device, characterized in that: comprising:
a first obtaining module obtaining time during a sealant material stays in a sealant receiving chamber;
a second obtaining module calculating a target temperature of the sealant material according to the obtained time and a desired sealant viscosity value; and
a heating module heating the sealant material to the target temperature, so as to lower an actual sealant viscosity to constantly keep in the desired sealant viscosity value.

12. The heating device according to claim 11, characterized in that: the first obtaining module periodically obtains the time during the sealant material stays in the sealant receiving chamber.

13. The heating device according to claim 11 or 12, characterized in that:
the heating module uses one of resistance heating and microwave heating.

14. The heating device according to claim 11 or 12, characterized in that:
the heating module has a temperature detection unit detecting the temperature of the sealant material.

15. The heating device according to claim 14, characterized in that: the temperature detection unit uses one of infrared detection and thermocouple detection.
